(19) United States
(12) Patent Application Publication
(10) Pub. No.: US 2025/0386496 A1
(43) Pub. Date: Dec. 18, 2025

(54) THREE-DIMENSIONAL MEMORY

(71) Applicant: Hangzhou HFC Semiconductor Co., Hangzhou (CN)

(72) Inventors: Youming LIU, Hangzhou (CN); Hokmin HO, Hangzhou (CN); Min LI, Hangzhou (CN); Jianbo LI, Hangzhou (CN)

(73) Assignee: Hangzhou HFC Semiconductor Co., Hangzhou (CN)

(21) Appl. No.: 18/761,297

(22) Filed: Jul. 1, 2024

(30) Foreign Application Priority Data
Jun. 18, 2024 (CN) 202410788142.2

(51) Int. Cl. H10B 43/27; H10B 43/30

(52) U.S. Cl. CPC H10B 43/27; H10B 43/30

(57) ABSTRACT

The present application discloses a three-dimensional memory, which belongs to the technical field of semiconductors. The three-dimensional memory includes: a substrate; a plurality of vertical channels arranged in the substrate; a source electrode arranged at an end of the vertical channel located at the substrate, where an entire row of the vertical channels share the same source; a drain doping region arranged at an end of the vertical channel away from the source; a gate dielectric layer arranged around the vertical channel between the drain doping region and the source; a metal gate arranged on the gate dielectric layer, where in a direction perpendicular to the source, the metal gates outside an entire row of the vertical channels are connected; and a drain electrode located on the substrate and connected to the drain doping region, where the drain electrode is arranged in parallel with the source electrode.

### CROSS REFERENCE TO RELATED APPLICATION

This application claims the benefit of and priority from Chinese Patent Application No. 202410788142.2, filed on Jun. 18, 2024, the entire disclosure of which is incorporated herein by reference for all purposes.

### TECHNICAL FIELD

The present application relates to the technical field of semiconductors, and in particular, relates to a three-dimensional memory.

### BACKGROUND

NOR Flash is a non-volatile memory. Its structural storage units are arranged in parallel and addressed in rows and columns. The minimum addressing unit is a byte. It is named NOR Flash because its logic circuit is similar to a “NOR gate”. It is characterized by high reading speed, random access capability, and high writing endurance. Its high reading speed makes it very suitable for applications that require fast data reading, such as code storage for microcontrollers or embedded processors.

### SUMMARY

One or more embodiments of the present application provides a three-dimensional memory, which includes at least: a substrate; a plurality of vertical channels provided in the substrate; a source provided at an end of the vertical channel located at the substrate, where an entire row of the vertical channels shares a same source; a drain doping region provided at an end of the vertical channel away from the source; a gate dielectric layer provided around the vertical channel between the drain doping region and the source; a metal gate provided on the gate dielectric layer, where the metal gates located outside the entire row of the vertical channels in a direction perpendicular to the source, are connected; and a drain located on the substrate and connected to the drain doping region, where the drain is in parallel with the source.

In one or more embodiments of the present application, the minimum area of a storage unit of the three-dimensional memory is 4F².

In one or more embodiments of the present application, the gate dielectric layer sequentially includes a tunneling layer, a storage layer, a buffer layer, and a barrier layer in sequence from a surface of the vertical channel.

In one or more embodiments of the present application, the tunneling layer includes a first tunneling layer, a second tunneling layer, and a third tunneling layer that are formed in sequence, the first tunneling layer, the third tunneling layer, and the buffer layer are silicon oxide layers, the second tunneling layer and the storage layer are silicon nitride layers, and the barrier layer is an aluminum oxide layer.

In one or more embodiments of the present application, the three-dimensional memory further includes a source doping region, and the top of the source is located in the source doping region, or the top of the source is flush with the bottom of the source doping region.

In one or more embodiments of the present application, a doping type of the drain doping region and a doping type of the source doping region are opposite to that of the vertical channel, and a doping concentration of the drain doping region is equal to a doping concentration of the source doping region.

In one or more embodiments of the present application, a plane where the bottom of the drain doping region is located coincides with a plane where the top of the metal gate is located, and a plane where the top of the source doping region is located coincides with a plane where the bottom of the metal gate is located.

In one or more embodiments of the present application, the three-dimensional memory further includes an interlayer dielectric layer, the drain is provided on the interlayer dielectric layer, and the drain is connected to the drain doping region through a conductive plug.

In one or more embodiments of the present application, in a direction perpendicular to the source, adjacent rows of the metal gates are separated by an insulating material layer.

In one or more embodiments of the present application, a hard mask layer and a spacer structure are provided at intervals around the drain doping region, the hard mask layer and the spacer structure completely surround the drain doping region, and the depth of the hard mask layer and the depth of the spacer structure are equal to the depth of the drain doping region.

### BRIEF DESCRIPTION OF DRAWINGS

In order to more clearly illustrate the technical solutions of the embodiments of the present application, the accompanying drawings required for describing the embodiments will be briefly introduced below. Please note, the accompanying drawings described below are only some embodiments of the present application. For ordinary technicians in this field, other accompanying drawings can be obtained based on these accompanying drawings without needing creative work.

FIG. 1 is a simplified schematic diagram of a three-dimensional memory according to one or more exemplary embodiments.

FIG. 2 is a schematic diagram of a gate dielectric layer according to one or more exemplary embodiments.

FIG. 3 is a schematic diagram of a three-dimensional memory according to one or more exemplary embodiments.

FIG. 4 is a cross-sectional view along an A-A direction of FIG. 3.

FIG. 5 is a cross-sectional view along a B-B direction of FIG. 3.

FIG. 6 is a cross-sectional view along a C-C direction of FIG. 3.

FIG. 7 shows a NOR flash memory array and an equivalent circuit diagram.

### DESCRIPTION OF REFERENCE NUMBERS

substrate 10; first isolation structure 11; hard mask layer 12; protective layer 13; second isolation structure 14; vertical channel 15; source 16; spacer structure 17; gate dielectric layer 18; tunneling layer 181; storage layer 182; buffer layer 183; barrier layer 184; first tunneling layer 1811; second tunneling layer 1812; third tunneling layer 1813; metal gate 19; insulating material layer 20; interlayer dielectric layer 21; conductive plug 22; drain 23; source doping region 101; drain doping region 102.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application.

It should be noted that the illustrations provided in these embodiments are only used to illustrate the basic concept of the present application in a schematic manner. Therefore, the drawings only show components related to the present application rather than being drawn according to the number, shape, and size of components in actual implementation. In actual implementation, the type, quantity, and scale of each component may be changed arbitrarily, and the component layout may also be more complicated.

In the present application, it should be noted that, if the terms “center”, “upper”, “lower”, “left”, “right”, “vertical”, “horizontal”, “inner”, “outer”, etc. appear, the orientation or position relationship indicated by them is based on the orientation or position relationship shown in the drawings, and is only for the convenience of describing the present application and simplifying the description, rather than indicating or implying that the device or element referred to must have a specific orientation, be constructed and operated in a specific orientation, and therefore cannot be understood as a limitation on the present application. In addition, if the terms “first” and “second” appear, they are only used for description and distinction purposes, and cannot be understood as indicating or implying relative importance.

With the rapid development of new-generation information technologies such as 5G, artificial intelligence (AI), and the Internet of Things (IoT), massive and extensive data needs to be stored and processed, and the demand for semiconductor memory is also growing rapidly. On today's wide variety of mobile terminals, such as wearable devices, small-sized, large-capacity embedded storage is required. There are more and more new demands for NOR Flash, which strongly requires new technological advances in NOR Flash. At present, the structure of NOR Flash is generally planar, and the planar structure is limited by the process node, resulting in a limited density of flash memory units in flash memory devices, which makes the flash memory devices less integrated and larger in size.

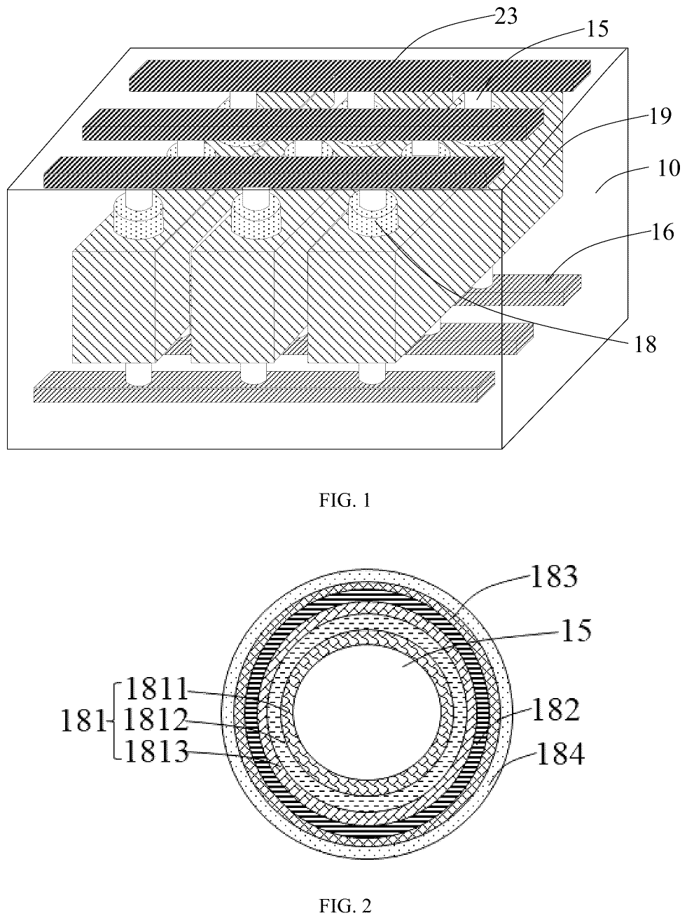

Please refer to FIG. 1, the present application provides a three-dimensional memory. The memory is, for example, a Nor Flash. The memory includes a substrate 10, a plurality of vertical channels 15, a source 16, a gate dielectric layer 18, a metal gate 19, and a drain 23. In one or more embodiments, the plurality of vertical channels 15 are arranged in an array in the substrate 10, the source 16 is arranged at an end of the vertical channel 15 located at the substrate 10, a whole row of vertical channels 15 share the same source 16, the gate dielectric layer 18 is arranged around the vertical channel 15, the metal gate 19 is arranged on the gate dielectric layer 18, and the drain 23 is located on the substrate 10. The drain 23 is arranged in parallel with the source 16, and the metal gate 19 is arranged perpendicularly to the drain 23 and the source 16. The metal gate 19 fully surrounds the vertical channel 15 and improves the electric field distribution of the gate. This may improve the performance of the memory. Through the three-dimensional memory, it is possible to break through the process node limitation, improve the density of the flash memory unit, and improve the integration of the memory, so as to meet the application of the memory in the new generation of information technology.

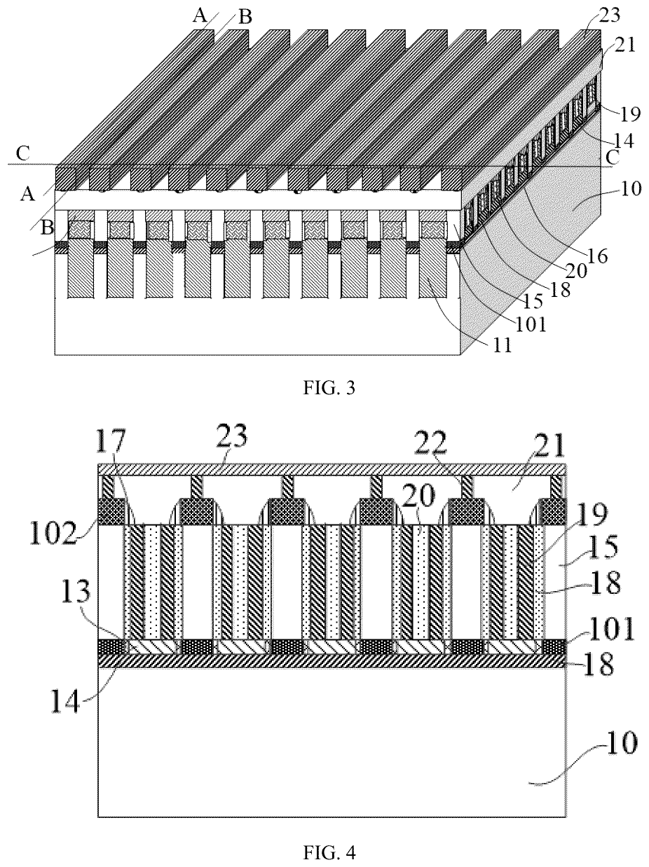

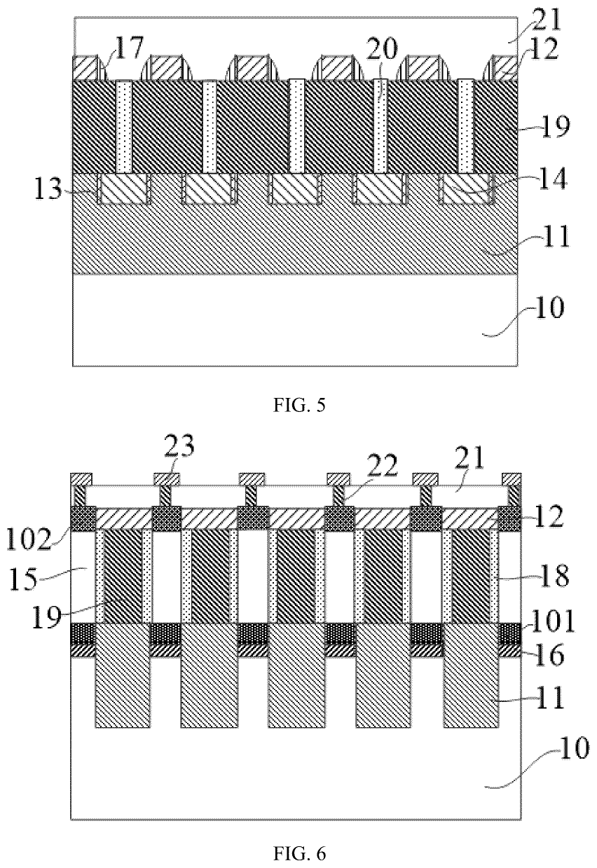

Please refer to FIG. 3 to FIG. 6, in one or more embodiments of the present application, FIG. 3 is a schematic diagram of a three-dimensional memory in exemplary embodiments, FIG. 4 is a cross-sectional view of FIG. 3 along an A-A direction, FIG. 5 is a cross-sectional view of FIG. 3 along a B-B direction, and FIG. 6 is a cross-sectional view of FIG. 3 along a C-C direction. To make the cross-sectional view clear, the cross-sectional views only show part of the vertical channels. In one or more embodiments, the substrate 10 may be made of any applicable semiconductor material, such as sapphire, silicon wafer, silicon carbide (SiC), gallium nitride (GaN), aluminum nitride (AlN), indium nitride (InN), silicon germanium (GeSi), or the like. In one or more embodiments, the substrate 10 includes a stacked structure made of any two or more of these semiconductor materials. In one or more embodiments, the substrate 10 is a single-crystal silicon substrate. In one or more embodiments, the substrate 10 is a P-type substrate or an N-type substrate. This application does not make any specific restrictions, and the type of the substrate can be selected according to the requirements of the memory.

Please refer to FIG. 3 to FIG. 6, in one or more embodiments of the present application, a first isolation structure 11 and a second isolation structure 14 are arranged in a substrate 10, and the first isolation structure 11 and the second isolation structure 14 are perpendicular to and intersect with each other. The depth of the second isolation structure 14 is less than the depth of the first isolation structure 11. The first isolation structure 11 and the second isolation structure 14 separate the substrate 10 into vertical channels 15 distributed in an array. For example, the isolation material filled in the first isolation structure 11 and the second isolation structure 14 is an insulating material, such as silicon oxide. The filling material of the first isolation structure 11 is, for example, the same as the filling material of the second isolation structure 14. In one or more embodiments, the depths of a plurality of first isolation structures 11 are equal, and the depths of a plurality of second isolation structures 14 are equal. The heights of the first isolation structure 11 and the second isolation structure 14 are lower than the surface of the substrate 10. A hard mask layer 12 is provided above the first isolation structure 11, and the surface of the hard mask layer 12 is, for example, flush with the surface of the substrate 10. There is a preset distance between the hard mask layer 12 and the first isolation structure 11 for arranging the metal gate 19. In one or more embodiments, the material of the hard mask layer 12 is different from the isolation material in the first isolation structure 11. For example, the material of the hard mask layer 12 is silicon nitride.

Please refer to FIG. 1 to FIG. 6, in one or more embodiments of the present application, the vertical channels 15 are distributed in an array in the substrate 10, and the depth of the vertical channels 15 is less than the depth of the first isolation structure 11. The vertical channel 15 is shaped, for example, as a cylinder or a prism. In one or more embodiments, the vertical channel 15 is a single-crystal silicon channel. This may improve the performance of the memory. By forming the plurality of vertical channels distributed in an array to form a three-dimensional memory device, the density of the flash memory unit may be increased, and the integration of the memory may be improved.

Please refer to FIG. 3 to FIG. 6, in one or more embodiments of the present application, a source doping region 101 is provided in the substrate 10, where the type of the doping ion in the source doping region 101 is opposite to the doping type of the substrate 10, the depth of the source doping region 101 is less than the depth of the first isolation structure 11. The depth of the source doping region 101 is, for example, one third to two-thirds of the depth of the first isolation structure 11.

Please refer to FIG. 3 to FIG. 6, in one or more embodiments of the present application, the bottom of the second isolation structure 14 is located in the source doping region 101. In one or more embodiments, the bottom of the second isolation structure 14 is flush with the bottom of the source doping region 101. A protective layer 13 is provided between the second isolation structure 14 and the substrate 10 on the sidewall, and the protective layer 13 is used to protect the vertical channel 15 when the source 16 is formed. The protective layer 13 is formed before the source 16 is formed, and after the source 16 is formed, an isolation material is provided on the source 16 to form the second isolation structure 14. In one or more embodiments, the source 16 is continuously provided below the second isolation structure 14 and the vertical channel 15, and an entire row of vertical channels 15 shares the same source 16. The sources between different rows of vertical channels 15 are separated by the first isolation structure 11. In one or more embodiments, the material of the source 16 is metal silicide. For example, the material of the source 16 is silicide of at least one metal selected from cobalt, nickel, tungsten, titanium, and platinum, so as to serve as the source electrode of multiple vertical channels 15, without requiring redundant wiring. Therefore, the connection performance may be improved. In one or more embodiments, the top of the source 16 is located in the source doping region 101, In one or more embodiments, the top of the source 16 is flush with the bottom of the source doping region 101. The source doping region 101 is provided to reduce the resistance of the source 16.

Please refer to FIG. 3 to FIG. 6, in one or more embodiments of the present application, a spacer structure 17 is disposed at an end of the vertical channel 15 away from the source 16. The spacer structure 17 is disposed at a position of the vertical channel 15 that is not in contact with the hard mask layer 12. For example, the spacer structure 17 and the hard mask layer 12 completely surround the vertical channel 15. The depths of the spacer structure 17 and the hard mask layer 12 on the vertical channel 15 are equal. The spacer structure 17 is, for example, a stacked structure of one or more of silicon oxide, silicon nitride, silicon oxynitride, and the like. The top of the spacer structure 17 is, for example, flush with the surface of the vertical channel 15. The spacer structure 17 is, for example, in an arc shape. The spacer structures 17 are not connected between adjacent vertical channels 15. The spacer structure 17 and the hard mask layer 12 completely surround the vertical channel 15 to protect the area where the drain of the memory unit is formed. This may facilitate the configuration of the drain.

Please refer to FIG. 1 to FIG. 6, in one or more embodiments of the present application, the surface of the first isolation structure 11, the surface of the protective layer 13, and the surface of the second isolation structure 14 are at the same level. For example, the surface of the first isolation structure 11, the surface of the protective layer 13, and the surface of the second isolation structure 14 are flush with the surface of the source doping region 101. A gate dielectric layer 18 is provided around the vertical channel 15 between the isolation structure and the spacer structure 17. In one or more embodiments, starting from the surface of the vertical channel, the gate dielectric layer 18 sequentially includes a tunneling layer 181, a storage layer 182, a buffer layer 183, and a barrier layer 184. In one or more embodiments, the tunneling layer 181 includes a first tunneling layer 1811, a second tunneling layer 1812, and a third tunneling layer 1813. The first tunneling layer 1811 and the third tunneling layer 1813 are, for example, silicon oxide layers. The second tunneling layer 1812 is, for example, a silicon nitride layer. In one or more embodiments, the tunneling layer 181 is a bandgap engineered ONO structure. The storage layer 182 is, for example, a silicon nitride layer. The buffer layer 183 is, for example, a silicon oxide layer. The barrier layer 184 is, for example, a layer with a high dielectric constant, such as an aluminum oxide layer. In one or more embodiments, the thickness of the tunneling layer 181, the thickness of the storage layer 182, the thickness of the buffer layer 183, and the thickness of the barrier layer 184 are selected according to the design requirements of the semiconductor device to meet the performance requirements of the memory. By providing the tunneling layer 181 of the ONO structure, the tunnel barrier of the ONO structure may improve the hole tunneling efficiency, improve the erasing speed, and reduce the erasing saturation, thereby improving the reliability of the tunneling layer. The barrier layer 184 may reduce gate injection during the erasing process. The buffer layer 183 is arranged between the barrier layer 184 and the storage layer 182. This may reduce charge leakage and improve the reliability of the memory.

Please refer to FIG. 1 to FIG. 6, in one or more embodiments of the present application, a metal gate 19 is provided on the gate dielectric layer 18. The metal material of the metal gate 19 is, for example, tungsten, copper, aluminum, titanium, or the like. The top of the metal gate 19 is flush with the top of the gate dielectric layer 18 and is in the same horizontal plane as the bottom of the spacer structure 17 and the bottom of the hard mask layer 12. For example, the plane where the bottom of the drain doping region 102 is located coincides with the plane where the top of the metal gate 19 is located, and the plane where the top of the source doping region 101 is located coincides with the plane where the bottom of the metal gate 19 is located. In one or more embodiments, in a direction perpendicular to the source 16, the metal gates 19 outside an entire row of vertical channels 15 are connected. In one or more embodiments, the metal gates 19 are arranged perpendicularly to the source 16. The metal gates 19 between adjacent rows of vertical channels 15 are separated by an insulating material layer 20 to control the entire row of flash memory units. In one or more embodiments, the insulating material layer 20 is silicon oxide or silicon nitride. The surface of the insulating material layer 20 is not higher than the surface of the substrate 10. For example, the surface of the insulating material layer 20 is flush with the surface of the metal gate 19. By surrounding the vertical channel 15 with the metal gate 19 to form a Gate-All-Around (GAA), the electric field distribution of the channel may be made more accurate, thereby improving the performance of the memory.

Please refer to FIG. 3 to FIG. 6, in one or more embodiments of the present application, a drain doping region 102 is provided at the top of the vertical channel 15. The type of the doping ion in the drain doping region 102 is opposite to the doping type of the substrate 10. The doping concentration of the drain doping region 102 is, for example, equal to the doping concentration of the source doping region 101. In one or more embodiments, the depth of the drain doping region 102 is equal to the depth of the spacer structure. For example, the plane where the bottom of the drain doping region 102 is located coincides with the plane where the top of the metal gate 19 is located. This may ensure the conduction of the device.

Please refer to FIG. 3 to FIG. 6, in one or more embodiments of the present application, an interlayer dielectric layer 21 is provided on the substrate 10. The interlayer dielectric layer 21 is filled between the spacer structures 17 and covers the surface of the substrate 10. The surface of the interlayer dielectric layer 21 is flat. In one or more embodiments, the interlayer dielectric layer 21 is silicon oxide or a material with a low dielectric constant (Low-K). The material with a low dielectric constant is, for example, one of silicon fluoride, silicon oxycarbide, silicon, oxyfluoride, and the like, so as to improve the reliability of subsequent metal plugs. A plurality of openings (not shown in the figure) are provided in the interlayer dielectric layer 21. In one or more embodiments, the openings are provided on the vertical channels 15. In one or more embodiments, a conductive material is provided in the openings to form a plurality of conductive plugs 22. The conductive plug 22 is connected to the drain doping region 102 on the vertical channel 15. Between the conductive material and the interlayer dielectric layer 21, for example, a metal barrier layer (not shown in the figure) is provided. The metal barrier layer is, for example, a material with good adhesion, such as tantalum (Ta), titanium (Ti), ruthenium (Ru), tantalum nitride (TaN), titanium nitride (TiN), or the like. This may enhance the adhesion between the conductive material and the sidewall of the opening, reduce the diffusion of the conductive material into the interlayer dielectric layer, reduce the electromigration phenomenon, and improve the electrical performance of the semiconductor structure. The conductive material is, for example, a low-resistance material, such as metal copper, metal aluminum, metal tungsten, or the like. In one or more embodiments, the conductive material is metal tungsten. In one or more embodiments, the conductive plug 22 is flush with the interlayer dielectric layer 21 on both sides of the opening.

Please refer to FIG. 3 to FIG. 6, in one or more embodiments of the present application, a drain 23 is provided on the interlayer dielectric layer 21. The material of the drain 23 is, for example, metal copper. In one or more embodiments, the drain 23 is in a strip shape and connected to a plurality of conductive plugs 22. The drain 23 is provided in parallel with the source 16. The metal gate 19 is provided perpendicularly to the drain 23 and the source 16. This may optimize the layout of the memory and improve the performance of the memory. The metal gate 19 is used as a word line (WL) to control the potential of the gate, the source 16 is used as a source line (SL) to control the potential of the source end, and the drain 23 is used as a bit line (BL) to control the potential of the drain end.

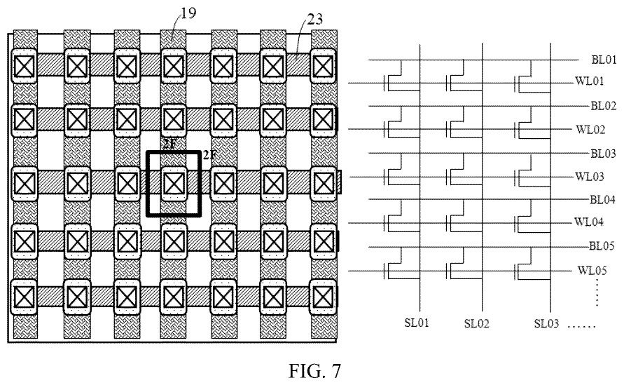

Please refer to FIG. 1 to FIG. 7, in one or more embodiments of the present application, in a three-dimensional memory, a NOR flash memory array with a minimum storage unit area of 4F² is obtained. This may greatly reduce the unit area of the small NOR flash memory array, thereby increasing the density of the NOR flash memory and reducing the cost. If data of a specified unit needs to be read, it is only needed to apply a voltage to the corresponding word line WL to turn on the transistor of the corresponding column, and then apply a reading voltage to the corresponding bit line BL. At this time, there is a current flowing from the bit line BL to the source line SL on the memory of the specified unit, and the state of the storage device can be obtained by reading the current on the corresponding source line SL. If data needs to be wrote to a specified storage unit, it is only needed to apply a voltage to the corresponding word line WL. At this time, the transistor of the corresponding column is in the turned-on state, and then a writing voltage is applied to the corresponding bit line BL or source line SL, and now the device is written to a required state. The specific application method is determined by the data to be written.

In summary, the present application provides a three-dimensional memory that may reduce the unit area of a small NOR flash memory array to increase the density of the NOR flash memory and reduce costs. It may make the electric field distribution of the channel more accurate and improve the performance of the memory. No extra wiring may be required, and the connection performance of the three-dimensional memory device may be improved. It may improve the hole tunneling efficiency, increase the erasing speed while reducing the erasing saturation at the same time, reduce charge leakage, and improve the reliability of the memory. Through the three-dimensional memory, it is possible to break through the process node limitations, increase the density of the flash memory unit, and improve the integration of the memory, thereby meeting the application of the memory in the new generation of information technology.

Through the three-dimensional memory provided by the present application, the integration of the memory may be improved, the hole tunneling efficiency may be improved, the erasing speed may be improved, and/or the reliability of the memory may be improved.

Please note, any product implementing the present application does not necessarily need to achieve all of the above-mentioned advantages at the same time.

References throughout the specification to “one embodiment,” “an embodiment,” or “a specific embodiment” mean that a particular feature, structure, or characteristic described in connection with the embodiment is included in at least one embodiment of the application, and not necessarily in all embodiments. Thus, various appearances of the phrases “in one or more embodiments,” “in an embodiment,” or “in a specific embodiment” in different places throughout the specification do not necessarily refer to the same embodiment. In addition, the particular features, structures, or characteristics of any specific embodiment of the application may be combined with one or more other embodiments in any suitable manner. It should be understood that other variations and modifications of the embodiments of the application described and illustrated herein may be possible in light of the teachings herein and are to be considered part of the spirit and scope of the application.

It should also be understood that the embodiments of the present application disclosed above are only used to help illustrate the present application. The embodiments do not describe all the details in detail, nor do they limit the application to the specific embodiments described. Obviously, many modifications and changes can be made according to the content of this specification. This specification selects and specifically describes these embodiments in order to better explain the principles and practical applications of the present application, so that those skilled in the art can well understand and use the present application. The present application is limited only by the claims and their full scope and equivalents.

What is claimed is:

1. A three-dimensional memory, comprising:
a substrate;
a plurality of vertical channels provided in the substrate;
a source provided at an end of the vertical channel located at the substrate, an entire row of the vertical channels shared a same source;
a drain doping region provided at an end of the vertical channel away from the source;
a gate dielectric layer provided around the vertical channel between the drain doping region and the source;
a metal gate provided on the gate dielectric layer, wherein the metal gates located outside the entire row of the vertical channels in a direction perpendicular to the source, are connected; and
a drain located on the substrate and connected to the drain doping region, wherein the drain is in parallel with the source.

2. The three-dimensional memory according to claim 1, wherein
a minimum area of a storage unit of the three-dimensional memory is 4F2.

3. The three-dimensional memory according to claim 1, wherein
the gate dielectric layer sequentially includes a tunneling layer, a storage layer, a buffer layer, and a barrier layer in sequence from a surface of the vertical channel.

4. The three-dimensional memory according to claim 3, wherein
the tunneling layer includes a first tunneling layer, a second tunneling layer, and a third tunneling layer that are formed in sequence,
the first tunneling layer, the third tunneling layer, and the buffer layer are silicon oxide layers,
the second tunneling layer and the storage layer are silicon nitride layers, and the barrier layer is an aluminum oxide layer.

5. The three-dimensional memory according to claim 1, further comprising a source doping region, wherein
a top of the source is located in the source doping region, or
the top of the source is flush with a bottom of the source doping region.

6. The three-dimensional memory according to claim 5, wherein
a doping type of the drain doping region and a doping type of the source doping region are opposite to that of the vertical channel, and
a doping concentration of the drain doping region is equal to a doping concentration of the source doping region.

7. The three-dimensional memory according to claim 5, wherein
a plane where a bottom of the drain doping region is located coincides with a plane where a top of the metal gate is located, and
a plane where a top of the source doping region is located coincides with a plane where a bottom of the metal gate is located.

8. The three-dimensional memory according to claim 1, further comprising an interlayer dielectric layer, wherein
the drain is provided on the interlayer dielectric layer, and
the drain is connected to the drain doping region through a conductive plug.

9. The three-dimensional memory according to claim 1, wherein
in a direction perpendicular to the source, adjacent rows of the metal gates are separated by an insulating material layer.

10. The three-dimensional memory according to claim 1, wherein
a hard mask layer and a spacer structure are provided at intervals around the drain doping region,
the hard mask layer and the spacer structure completely surround the drain doping region, and
a depth of the hard mask layer and a depth of the spacer structure are equal to a depth of the drain doping region.
